(19) United States
(12) Patent Application Publication
(10) Pub. No.: US 2022/0283452 A1
(43) Pub. Date: Sep. 8, 2022

(54) Optical Cavity Devices Using Stacked Multi-Quantum Wells

(71) Applicant: Fathom Radiant, PBC, Boulder, CO (US)

(72) Inventor: Erik C. Nelson, Pleasanton, CA (US)

(21) Appl. No.: 17/382,069

(22) Filed: Jul. 21, 2021

Related U.S. Application Data
(60) Provisional application No. 63/054,594, filed on Jul. 21, 2020.

(51) Int. Cl. G02F 1/017; H01L 27/144; H01L 31/0352; H01L 31/11; H01L 31/0232

(52) U.S. Cl. CPC G02F 1/017; H01L 27/1446; H01L 31/035236; H01L 31/11; H01L 31/02327; G02F 1/0159

(57) ABSTRACT

An optical cavity device has two spaced-apart multiple quantum well (MQW) regions, a central electrode terminal and two marginal electrode terminals. The central electrode terminal contacts a central electrode layer between the MQW regions, and each marginal electrode terminal contacts a separate marginal electrode layer on the other side of each MQW region. There are also two mirrors outside of the MQW regions, forming the cavity. The device has a less-absorptive state and a more-absorptive state selected by varying the voltage between the anode and at least one of the two cathodes. The two marginal electrode terminals may be electrically connected, or the voltage between the central electrode terminal and the marginal electrode terminals may be varied independently. These devices may form an array of detectors, modulators or both. In an array, multiple devices may share a common electrode layer. Devices may be stacked, with two or more anode terminals and two more cathode terminals alternating in the stack. Three or more MQW regions are then formed with either an anode layer or a cathode layer between each MQW region.

### BACKGROUND OF THE INVENTION

### Field of the Invention

The present invention relates to optical cavity devices using stacked regions of multi-quantum wells.

### Discussion of Related Art

The asymmetric Fabry-Perot modulator (AFPM) 100 is a device very similar in structure to a vertical cavity surface-emitting laser (VCSEL). See FIG. 1 (prior art). It has a cavity formed by two mirrors 104 that are formed by, for example, alternating layers of semiconductor alloys of varying composition, and thus refractive index.

These are distributed Bragg reflectors (DBRs). Within the cavity is a multiple quantum well (MQW) region 103 that is unintentionally doped (considered intrinsic for this discussion). On one side of the MQW is a p-type region 110 and the other an n-type region 108, forming a diode 101 (see FIG. 4). When the diode is reverse biased the QWs have an electric field across them that results in spatial separation of the electron and hole wavefunctions, a reduction in the band gap of the material and a broadening of the absorption peak.

This is due to a phenomenon referred to as the Quantum-confined Stark Effect. See FIG. 2 (prior art). Utilizing these effects, one can move the absorption of the MQW in and out of resonance with the optical cavity. Initially, with no applied bias, the absorption is not aligned to the cavity resonance. However, upon application of a reverse bias, the absorption is redshifted and can be aligned to the cavity resonance. Light of the wavelength of resonance that is incident on the device thus selectively experience a weak or strong absorption, or a strong or weak reflection. This is how the device is used as a surface-normal reflective modulator. The device may be configured to operate in transmission mode as well, where the changing absorption modulates the amount of light transmitted through the device. Additionally, the absorption of light in the device generates a photocurrent that may be measured by a circuit, allowing the device to function as a detector. The same device may function as both a modulator and detector depending on the design of the circuitry to which it is connected.

The magnitude of the shift in the absorption spectrum is proportional to the electric field across the quantum wells. To maximize the difference between the high and low reflectance states, one wants a large difference in absorption between the two states. To achieve this, one positions the absorption peak wavelength in the initial, high reflectance state at a wavelength far from the cavity resonance. Then, to sufficiently shift the absorption spectrum into alignment with the cavity resonance, a large electric field is required to achieve the low reflectance state. See FIG. 3 (prior art).

For a fixed voltage, the field is higher the shorter the length of the intrinsic region between the two contacts (E=V/d). The length of the intrinsic region is defined by the MQW region plus some thin intrinsic buffer region on each side that serves to keep dopant atoms away from the QWs. A simple schematic of this structure is shown in FIG. 4B (prior art). At left the MQW region 407 is defined by a dark line. In the magnified portion at right, the quantum well region 103 is black lines and the intrinsic regions 412 around them are white lines. In this example the p-type layer is above the MQW region and the n-type layer is below.

The number of QWs defines the maximum achievable absorption, and is thus also an important parameter. One way to think of this is that the cavity results in many “bounces” through the device. Each QW has a given single pass absorption, and thus for a fixed number of bounces, more QWs means higher absorption when we align the cavity resonance and absorption spectrum.

There is a tension between the number of QWs (maximum absorption) and the achievable field at a given voltage, since more QWs also results in a greater intrinsic region thickness (again, E=V/d). The effect of this is a reduced shift in the absorption for a given applied voltage, akin to shifting the two curves in FIG. 3 closer together.

Furthermore, the electronic circuits that drive the modulator can only supply a limited range of voltages. Ideally the circuit utilizes the core voltage of the logic, however that voltage is typically low (<0.9V) and is reduced further in the most advanced process nodes. One can utilize special I/O transistors to enable use of higher voltages (e.g. 1.8V), however this comes at the price of physical space (I/O transistors are typically larger) and energy consumption in the circuit. To summarize, one wants the ability to apply a large electric field across the quantum wells, however the maximum achievable electric field is limited by the intrinsic region thickness AND the maximum available voltage.

A need remains in the art for apparatus and methods to provide improved multi-quantum well devices.

### SUMMARY OF THE INVENTION

The present invention relates to three or more terminal devices having multiple quantum well regions stacked within the same optical cavity. Generally the quantum well regions are disposed between two mirrors, such as distributed Bragg reflectors (DBRs). The mirrors may be formed as part of the cavity or may be external, or a combination. The devices may be monolithic, meaning in the same epitaxy growth run. Some embodiments cut the required voltage for the device in half or more.

In some embodiments, arrays of modulators or detectors are provided, and the terminals are addressed at the pixel level. Embodiments utilize a stack of two or more devices on top of one another, grown in the same epitaxial growth run. The devices may be stacked in alternating polarity and share the p-contact in the center of the device. The DBRs may be within two n-type regions for an n/p/n arrangement where the p-contact layer in the center is shared. In a p/n/p device, the n-contact layer in the center is shared, and the DBRs might be disposed within the p-type layers.

Embodiments permit devices to operate at approximately half the voltage. Due to the two intrinsic regions, it generally isn't reduced by quite half, but it is easily reduced by 40% or 45%. This allows one to utilize the core voltage of the ASIC and avoid I/O transistors, simplifying the system, saving area in the circuit, and reducing energy consumption.

An example optical cavity device has a stack of layers including two spaced-apart multiple quantum well (MQW) regions, a central electrode terminal and two marginal electrode terminals. The central electrode terminal contacts a central electrode layer between the MQW regions, and each marginal electrode terminal contacts a separate marginal electrode layer on the other side of each MQW region from the central electrode layer. There are also two mirrors outside of the MQW regions, forming the cavity. The device has a less-absorptive state and a more-absorptive state selected by varying the voltage between the anode and at least one of the two cathodes.

In some embodiments the two marginal electrode terminals are electrically connected. In others, the voltage between the central electrode terminal and the marginal electrode terminals may be varied independently. For example, the relative voltage between the central electrode terminal and one of the marginal electrode terminals is varied, while the relative voltage between the central electrode terminal and the other marginal electrode terminal remains the same.

These devices may be configured as detectors, modulators or both. They may form an array of detectors, modulators or both. In an array, multiple devices may share a common electrode layer.

The MQW regions, the central electrode terminal layer, and the marginal electrode terminal layers (and optionally the mirrors) may be all grown in a single epitaxy growth run. The mirrors might be distributed Bragg reflectors. They may be formed between the marginal electrode terminal layers. In other embodiments layers may be bonded in another manner. The mirror may be external.

Such devices may also be stacked. In that case a device would have two or more anode terminals and two more cathode terminals alternating in the stack. Three or more MQW regions are then formed with either an anode layer or a cathode layer between each MQW region.

Each anode layer and a different anode terminal and each cathode layer contacts a different cathode terminal. Two mirrors are disposed on either side of all of the MQW regions. The device has at least one less-absorptive state and at least one more-absorptive state. The state is selected by varying voltages between anode terminals and cathode terminals in various combinations. In some embodiments, either some of the anode terminals are electrically connected together or some of the cathode terminals are electrically connected together or both.

Again it may be useful to grow the anode layers, the cathode layers, and the MQW regions in a single epitaxy growth run, and in some cases the mirrors as well.

These devices may form arrays. They may be configured as detectors, modulators, or both.

### BRIEF DESCRIPTION OF THE DRAWINGS

FIG. 1 (prior art) is a schematic drawing of a side-cutaway view of an AFPM structure similar to a VCSEL device.

FIG. 2 (prior art) is a schematic drawing illustrating the quantum-confined Stark effect.

FIG. 3 (prior art) is a plot showing the relationship between applied voltage and the absorption peak.

FIG. 4A (prior art) and FIG. 4B (prior art) show a portion of the device of FIG. 1 in more detail. FIG. 4A is a circuit diagram and FIG. 4B is an expanded cutaway view of the stacked portion.

FIGS. 5A, 5B, and 5C are schematic drawings illustrating a device with multiple thin MQW regions stacked together according to the present invention. FIG. 5A is a circuit diagram of a two-state device. FIG. 5B is a side cutaway view showing the layer structure of the embodiment of FIG. 5A. FIG. 5C is a circuit diagram of a three-state device having the layer structure of FIG. 5B.

FIG. 6A is a schematic drawing of a cross-section of an example two-device stack according to the present invention.

FIG. 6B is a schematic drawing of a top view of the metal contacts in the stack of FIG. 6A.

FIG. 7 is a side cutaway view of the layer structure of the of a stacked device according to the present invention.

FIGS. 8A and 8B show a bulk device. FIG. 8A is a top view and FIG. 8B is a side cutaway view.

FIG. 9 is a top view of a 2D pixel array according to the present invention.

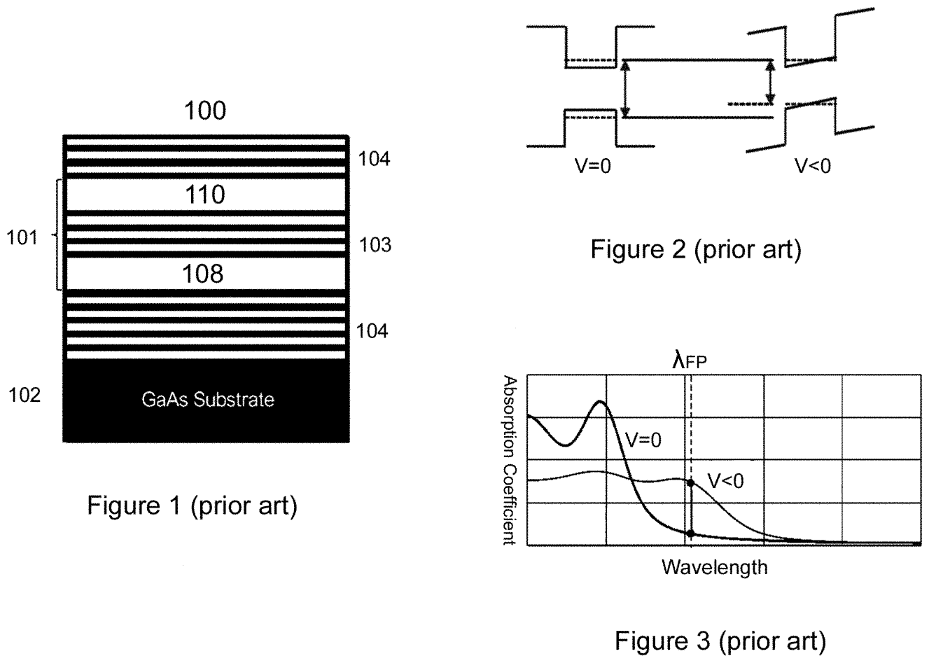

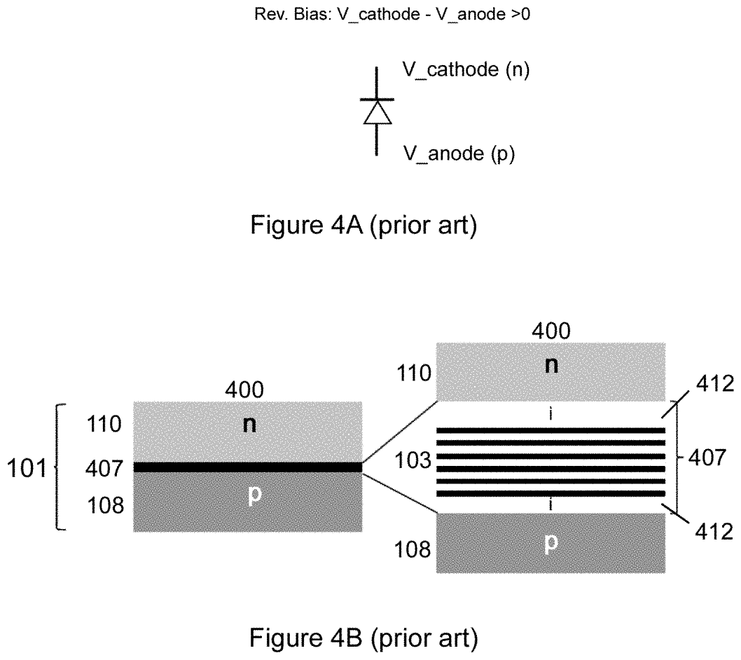

### DETAILED DESCRIPTION OF THE INVENTION

Table 1 shows elements of the present invention and their associated reference numbers.

| Ref. no. | Element |
|---|---|
| 100 | AFPM structure |
| 101 | Fabry-Perot cavity |
| 102, 602 | Substrate |
| 103 | Multiple quantum well structure |
| 104, 604 | Distributed Bragg reflector (DBR) |
| 108 | p-type region |
| 110 | n-type region |
| 400 | Single MQW region device portion |
| 406 | MQW region |
| 407 | MQW region with intrinsic layers |
| 408, 608 | p-type region (anode layer) |
| 410 | n-type region |
| 412 | Intrinsic regions |
| 500 | Double MQW region device |
| 509 | Double MQW region stack |
| 600 | Example double MQW region device stack |
| 618, 918 | Anode contact to p-type layer |
| 620, 920 | Cathode contact to n-type layer |
| 621, 921 | Cathode contact to buried n-type layer |
| 622 | Passivation |
| 624 | n-contact layer (cathode) |
| 626 | n-contact layer (cathode) |
| 700 | Stacked device embodiment |

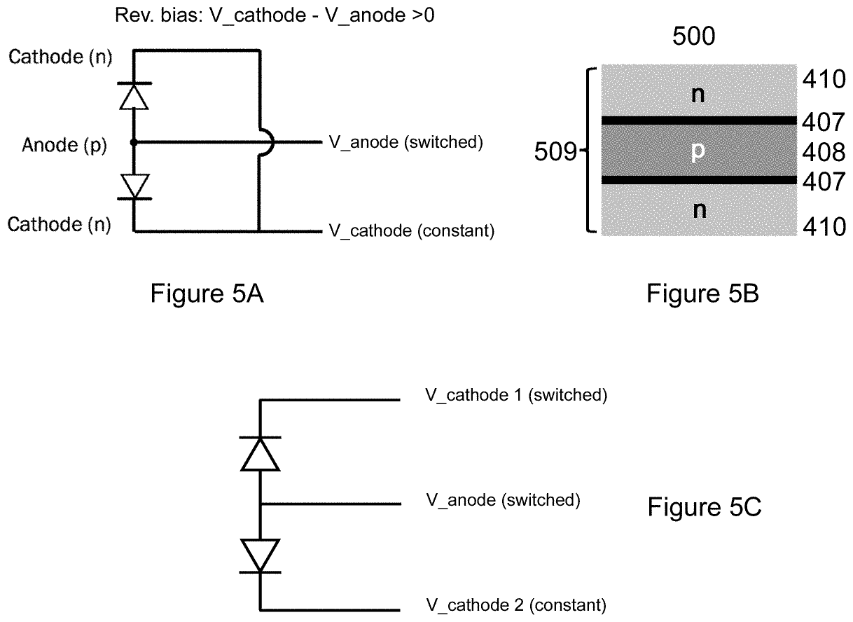

The invention utilizes a stack of two or more devices on top of one another, often grown in the same epitaxial growth run. FIGS. 5A, 5B, and 5C are schematic drawings illustrating a device with multiple thin MQW regions stacked together according to the present invention. FIG. 5A is a circuit diagram of a two-state device. FIG. 5B is a side cutaway view showing the layer structure of the embodiment of FIGS. 5A and 5B. FIG. 5C is a circuit diagram of a three-state device having the layer structure of FIG. 5B.

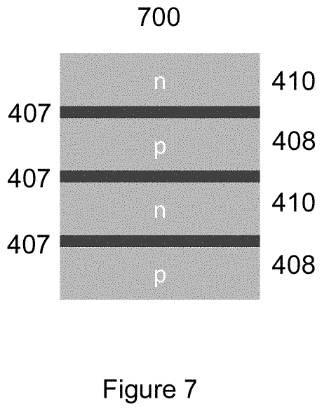

FIGS. 5A-C are schematic drawings illustrating a device stack 509 with multiple thin MQW regions 407 stacked together according to the present invention. FIG. 5B shows a two-device stack 509, though in practice more than two devices could be stacked, and the polarity of the shared contact could be reversed (see FIGS. 7A and 7B). The devices are stacked in alternating polarity, and in this example they share the p-contact in the center of the device. The DBRs 104 are within the two n-type regions and are not shown in FIG. 5. This arrangement can be repeated to stack more than two layers: n-MQW-p(shared)-MQW-n-MQW-p(shared)-MQW- . . . PNP devices may also be used, with layers p-MQW-n(shared)-MQW-p-MQW-n(shared)-MQW- . . . .

This sort of embodiment permits two devices operating at half the voltage as shown in FIG. 5A, because of the shared p-type contact. This allows one to utilize the core voltage of the ASIC and avoid I/O transistors, simplifying the system, saving area in the circuit, and reducing energy consumption.

FIG. 5C shows a three state device. In addition to lowering the required voltage, the ability to easily generate 3 states in the modulator using two voltages would also be valuable. In FIG. 5A, the cathode terminals of the device are connected in the drive circuit and they are kept at a constant voltage, while the shared anode contact is switched between two voltage states, for example, 0V and 0.75V. This modulates the two MQW diodes simultaneously. In FIG. 5C, the two pixel-level contacts (shared anode, and the pixel-specific cathode) may be modulated independently. Applying the same voltage to the pixel-specific cathode as to the common cathode, while modulating the anode, results in both diodes changing states, the same as the device in FIG. 5A. However, the pixel-specific cathode voltage may instead be switched to offset the changing anode voltage, maintaining the relative voltage between the anode and pixel-specific cathode as the anode voltage changes. This creates a third state, where only the bottom device has changed is absorption/reflection. This is an intermediate state for the total device, partway between the low and high reflectance states of the device in FIG. 5A. The voltage applied to the pixel-specific cathode would necessarily be the same as that applied to the anode to maintain the voltage across the device, so a new voltage level need not be added to the circuit.

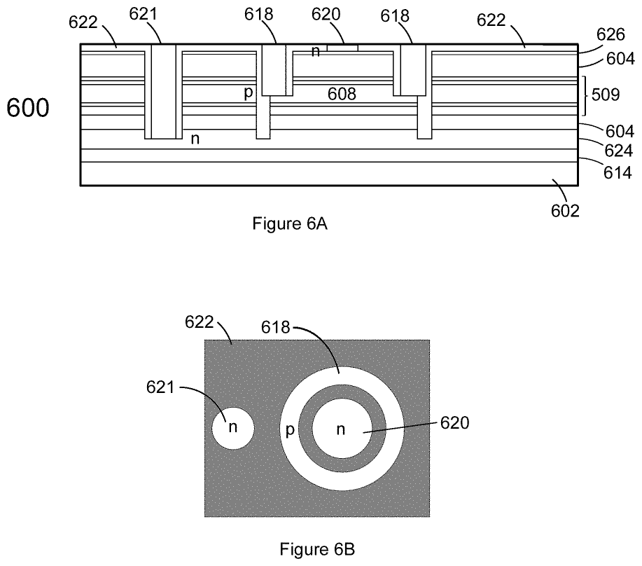

A specific embodiment of a two-device stack is shown in FIGS. 6A and 6B. This embodiment is structured as follows. Reference is made to the polarity of the device in the illustrations, which is not inclusive of all possible arrangements but is simply an example. To operate this device, one creates two contacts per pixel (an anode and cathode connection), and uses (in this example) a common cathode contact 621 shared among the bottom MQW region of all pixels. One cathode contact 620 connects to n-type layer 626 at the top of the device. An anode contact 618 is, for example, formed by etching a ring down to expose the buried p-layer 608, and a contact is electroplated up from that layer to the top of the device (subsequent CMP planarizes that metal). The common cathode contact 621 is also formed by dry etching (to the buried common cathode layer 624), plating, and CMP. Layers 624 and 626 are generally highly doped (n++). The two cathode terminals 620, 621 are electrically connected in the metal routing layers of the ASIC to which the device is attached. The ASIC is driving a circuit like that shown in FIG. 5A.

FIG. 6A is an example 600 of how this stack might look in cross-section. Given a cylindrical pixel 600, its center is defined by the contact metal 620 at upper n-type layer 626. It has a ring contact 618 that reaches down to the p-layer 608. Next to the pixel is a via contact 621 that reaches down to the lower n-type layer 624. Layers 604 are the DBR mirrors. FIG. 6B is a top view of the device showing the metal contacts 618, 620, 621 for device 600. This arrangement could be repeated to create an arrangement of such pixels in a 2D array (see FIG. 9). This embodiment has an etch stop layer 614 to allow removal of substrate 602.

FIG. 7 is a side cutaway view showing the layers of a stacked device. The device has two or more anode terminals and two more cathode terminals alternating in the stack. Three or more MQW regions are then formed with either an anode layer or a cathode layer between each MQW region.

Each anode layer contacts a different anode terminal and each cathode layer contacts a different cathode terminal. Two mirrors (not shown) are disposed on either side of all of the MQW regions to form the cavity. The device has at least one less-absorptive state and at least one more-absorptive state. The state is selected by varying voltages between anode terminals and cathode terminals in various combinations. In some embodiments, either some of the anode terminals are electrically connected together or some of the cathode terminals are electrically connected together or both.

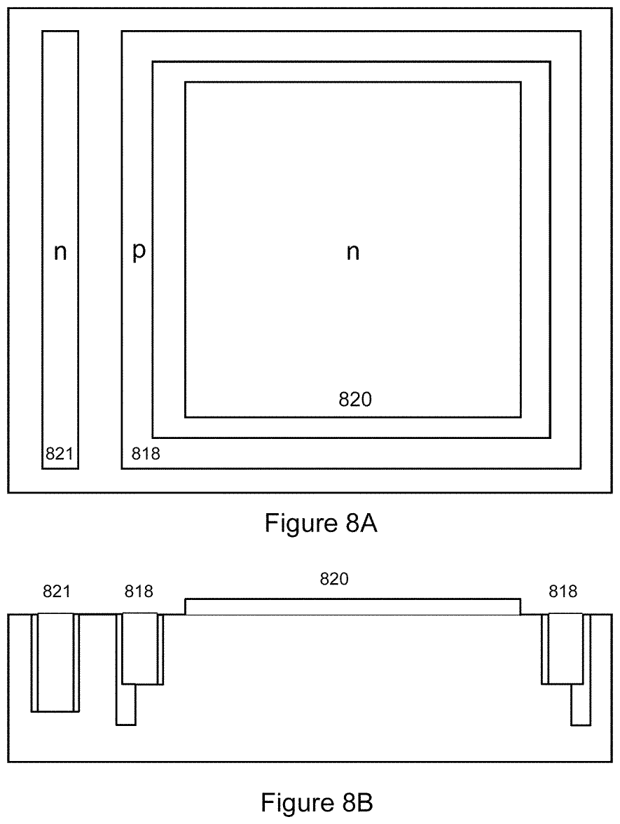

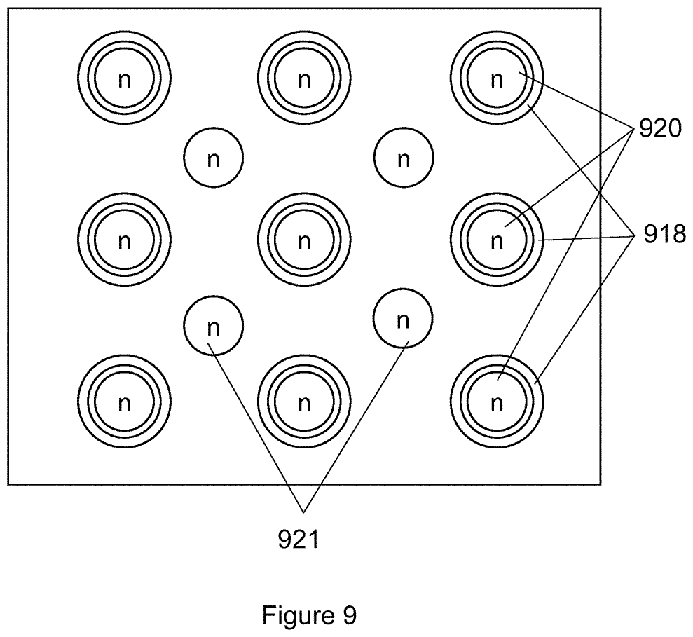

FIGS. 8A and 8B show a bulk device. FIG. 8A is a top view and FIG. 8B is a side cutaway view. The layer structure is omitted for simplicity, but might look like the structure shown in FIG. 6A. A bulk device may be much larger in area than a pixelated device, potentially to operate on a large incident spot or beam. The size of the device could be, for example, 50 um to 1 mm. In this example, the device is square.

FIG. 9 is a top view of a 2D pixel array according to the present invention. Each pixel has an anode contact to a p-type layer and a cathode contact to an n-type layer, in a manner similar to FIG. 6A. However, fewer cathode contacts to the buried n-type layer are required because the buried cathode layer is shared among multiple or all pixels and is thus contacted only periodically across the area of the pixels. One could fabricate this device with one n-contact via (the far-left deep contact 621 on FIG. 6) per 10, 20, 100 pixels or more, depending on the conductivity of the n++ layer 624.

While the exemplary preferred embodiments of the present invention are described herein with particularity, those skilled in the art will appreciate various changes, additions, and applications other than those specifically mentioned, which are within the spirit of this invention. Note that herein, the terms “top” and “bottom” are used for convenience in discussing the figures. In practice, these devices are generally flipped over and then are operated while upside down relative to the figures. Any orientation is part of the invention.

Also note that opposite polarity (e.g. PNP devices) are part of the invention. Each switched terminal need not have only two voltage stages. There could be many discrete states between the minimum and maximum voltage. Such a mode of operation could be used to achieve a near-analog rather than a digital optical output.

The contact layers in the epitaxy may be within the boundary of the DBRs (intracavity contacts), which would utilize dry etching through the upper DBR to reach the contact layer underneath. In addition, the DBRs need not be grown by epitaxy. They may be deposited on the semiconductor wafer, for example by evaporating or sputtering dielectric layers of differing refractive index. This is sometimes referred to as an external DBR.

The entire device may be formed monolithically (one epitaxial growth run) or it may be formed by various other processes including but not limited to epitaxial regrowth (each MQW region grown in separate epitaxial growth runs) or bonding of two wafers, with an n/MQW/p and p/MQW/n structure, that each were grown by separate epitaxy processes.

Some embodiments may not require removal of the substrate, and could omit the etch stop within the epitaxy structure. The invention is applicable to a variety of semiconductor material systems, including AlGaAs, InP, and their alloys; GaN; AlInGaP; Si and SiGe; and others. Common substrates include GaAs, InP, sapphire, GaN, SiC, Si, and Ge. The contact 618 that reaches the embedded layer 608 in the middle doesn't have to be a ring. It could be for example a pillar.

What is claimed is:

1. An optical cavity device having a stack of layers, the device comprising:
two spaced-apart multiple quantum well (MQW) regions;
a central electrode terminal and two marginal electrode terminals, the central electrode terminal configured to contact a central electrode layer disposed between the MQW regions, and each marginal electrode terminal configured to contact a separate marginal electrode layer on the other side of each MQW region from the central electrode layer;
two mirrors disposed on either side of both of the MQW regions;
wherein the device has a less-absorptive state and a more-absorptive state, the states selected by varying at least one voltage between the anode and at least one of the two cathodes.

2. The device of claim 1 wherein the two marginal electrode terminals are electrically connected.

3. The device of claim 1 wherein the relative voltage between the central electrode terminal and one of the marginal electrode terminals is varied, while the relative voltage between the central electrode terminal and the other marginal electrode terminal remains the same.

4. The device of claim 1 wherein the relative voltage between the central electrode terminal and one of the marginal electrode terminals is varied, while the relative voltage between the central electrode terminal and the other marginal electrode terminal varies independently.

5. The device of claim 1 configured as a detector.

6. The device of claim 1 configured as a modulator.

7. The device of claim 1 configured to operate as both a modulator and a detector.

8. The device of claim 1 wherein the MQW regions, the central electrode terminal layer, and the marginal electrode terminal layers are all grown in a single epitaxy growth run.

9. The device of claim 8 wherein the mirrors are also formed in a single epitaxy growth run with the MQW layers, central electrode terminal layer, and the marginal electrode terminal layers.

10. The device of claim 1 wherein the mirrors are distributed Bragg reflectors (DBR).

11. The device of claim 10 wherein the mirrors are formed between the marginal electrode terminal layers.

12. Multiple devices according to claim 1 formed as an array of either:
modulators; or
detectors; or
both modulators and detectors.

13. The array of claim 12 wherein multiple devices share a common electrode layer.

14. An optical cavity device having a stack of layers, the device comprising:
two anode terminals and two cathode terminals;
two anode layers and two cathode layers, the anode layers and the cathode layers alternating in the stack, the anode layers each configured to contact a different anode terminal and the cathode layers each configured to contact a different cathode terminal;
three spaced-apart multiple quantum well (MQW) regions disposed between the anode and cathode layers such that an anode layer or a cathode layer is between each two MQW regions;
two mirrors disposed on either side of all of the MQW regions;
wherein the device has a less-absorptive state and a more-absorptive state, the state selected by varying voltages between anode terminals and cathode terminals.

15. The device of claim 14 wherein two of the anode terminals are electrically connected together.

16. The device of claim 14 wherein two of the cathode terminals are electrically connected together.

17. The device of claim 14 wherein the MQW regions, the anode terminal layers, and the cathode terminal layers are all grown in a single epitaxy growth run.

18. The device of claim 14 wherein the mirrors are also formed in a single epitaxy growth run with the MQW regions, the anode terminal layers, and the cathode terminal layers.

19. The device of claim 14 configured as either:
a detector;
a modulators; or
both a modulator and a detector.

20. Multiple devices according to claim 14 formed as an array of either:
modulators; or
detectors; or
both modulators and detectors.

21. The array of claim 20 wherein multiple devices share a common anode layer or a common cathode layer.
